(19) United States
(12) Patent Application Publication
(10) Pub. No.: US 2026/0190307 A1
(43) Pub. Date: Jul. 2, 2026

(54) DISPLAY DEVICE

(71) Applicant: LG Display Co., Ltd., Seoul (KR)

(72) Inventor: HeeSuk PANG, Paju-si (KR)

(73) Assignee: LG Display Co., Ltd., Seoul (KR)

(21) Appl. No.: 19/344,897

(22) Filed: Sep. 30, 2025

(30) Foreign Application Priority Data
Dec. 30, 2024 (KR) 10-2024-0201239

(51) Int. Cl. H05K 7/20

(52) U.S. Cl. CPC H05K 7/20963

(57) ABSTRACT

According to an aspect of the present disclosure, a display device includes a display part configured to display an image, an encapsulation part disposed above the display part, a heat dissipation sheet disposed above the encapsulation part and having a plurality of grooves, and a metal plate alternately inserted into the plurality of grooves. A part of the metal plate is located above the heat dissipation sheet, and another part of the metal plate is located below the heat dissipation sheet. As a result, deformation generated when the heat dissipation sheet is thermally expanded can be prevented from being directly transmitted to the printed circuit board and the flexible film, thereby suppressing or minimizing damage to the flexible film.

### CROSS-REFERENCE TO RELATED APPLICATIONS

This application claims priority to Korean Patent Application No. 10-2024-0201239 filed on Dec. 30, 2024, in the Korean Intellectual Property Office, the disclosure of which is hereby expressly incorporated by reference into the present application.

### BACKGROUND

### Field

The present disclosure relates to a display device that increases rigidity of a display panel and enhances heat dissipation.

### Description of the Related Art

Currently, as the world enters a full-fledged information era, the field of display devices that visually display electrical information signals is rapidly developing, and research continues to improve the performance of various display devices, including thinning, weight reduction, and low power consumption.

Representative display devices include a liquid crystal display (LCD), an electro-wetting display (EWD), and an organic light emitting display (OLED).

Among these display devices, an electroluminescent display device including an organic light emitting display device is a self-emitting display device and does not require a separate light source unlike a liquid crystal display device, and thus can be manufactured to have a light weight and a small thickness. In addition, the electroluminescent display device is advantageous not only in terms of power consumption because the electroluminescent display device operates at a low voltage, but also in terms of color implementation, a response speed, a viewing angle, and a contrast ratio (CR), so it is expected to be utilized in various fields.

### SUMMARY OF THE DISCLOSURE

An object to be achieved by the present disclosure is to provide a display device in which an encapsulation structure of a multilayer structure is applied to increase rigidity of a display panel and improve a heat dissipation effect.

Another object to be achieved by the present disclosure is to provide a display device in which damage to a bonding unit due to thermal expansion is prevented or minimized when an encapsulation structure of a multilayer structure is applied.

Objects of the present disclosure are not limited to the above-mentioned objects, and other objects, which are not mentioned above, can be clearly understood by those skilled in the art from the following descriptions.

In order to achieve the above-mentioned objects, a display device according to an example embodiment of the present disclosure includes a display part configured to display an image, an encapsulation part disposed above the display part, a heat dissipation sheet disposed above the encapsulation part and having a plurality of grooves, and a metal plate alternately inserted into the plurality of grooves, a part of the metal plate can be located above the heat dissipation sheet, and another part of the metal plate can be located below the heat dissipation sheet.

A display device according to another embodiment of the present disclosure includes a display part, an encapsulation part disposed above the display part, a heat dissipation sheet disposed above the encapsulation part and having a plurality of grooves, a metal plate alternately inserted into the plurality of grooves, a printed circuit board disposed above the metal plate and the heat dissipation sheet, and a plurality of flexible films disposed to cover one end of the printed circuit board from a pad part of the display part, the metal plate can be inserted into the plurality of grooves of the heat dissipation sheet so as to be spaced apart from the heat dissipation sheet so as not to be bound by thermal expansion of the heat dissipation sheet.

Other detailed matters of the embodiments of the present disclosure are included in the detailed description and the drawings.

According to aspects of the present disclosure, by introducing an encapsulation structure of a multilayer structure including a relatively thick reinforcing substrate, sufficient rigidity and heat dissipation effects can be secured.

According to aspects of the present disclosure, a thin metal plate is alternately inserted through a plurality of grooves of the heat dissipation sheet so that the heat dissipation sheet and the flexible film are fastened in a spaced apart manner. Accordingly, the deformation generated as the heat dissipation sheet undergoes thermal expansion is prevented or minimized from being directly transferred to the printed circuit board and the flexible film, thereby suppressing or preventing damage to the flexible film. In addition, a structural advantage of enhancing stability can be provided by minimizing the influence of displacement and warpage caused by thermal expansion while maintaining mechanical coupling.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view schematically illustrating a display device according to an embodiment of the present disclosure.

FIGS. 2 and 3 are enlarged views of a part A of FIG. 1 according to an example of the present disclosure.

FIG. 4 is a cross-sectional view illustrating a sub pixel of a display device according to an example embodiment of the present disclosure.

FIG. 5 is a cross-sectional view taken along the line IIa-IIa′ of FIG. 2 according to an example of the present disclosure.

FIG. 6 is a cross-sectional view taken along the line IIb-IIb′ of FIG. 2 according to an example of the present disclosure.

FIG. 7 is a cross-sectional view taken along the line III-III′ of FIG. 3 according to an example of the present disclosure.

FIGS. 8A to 8H are plan views sequentially illustrating a part of a manufacturing process of the display device of FIG. 1 according to an embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms such as “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may” and vice versa.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings. All the components of each display device/apparatus according to all embodiments of the present disclosure are operatively coupled and configured.

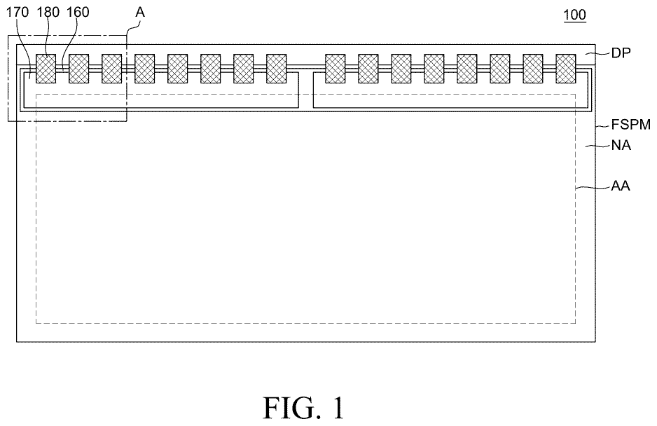

FIG. 1 is a plan view schematically illustrating a display device according to an embodiment of the present disclosure.

Referring to FIG. 1, a display device 100 according to an embodiment of the present disclosure can include a display part DP, an encapsulation part FSPM, a heat dissipation sheet 160, a printed circuit board 170, and a flexible film 180.

The display part DP is a panel for displaying images to a user.

The display part DP can include a display element for displaying an image, a driving element for driving the display element, and wirings for transmitting various signals to the display element and the driving element. The display element can be differently defined depending on the type of the display part DP. For example, when the display part DP is an organic light emitting display panel, the display element can be an organic light emitting element including an anode, an organic layer, and a cathode. For example, when the display part DP is a liquid crystal display panel, the display element can be a liquid crystal display element.

Hereinafter, even though it is assumed that the display part DP is an organic light emitting display panel, the display part DP is not limited to the organic light emitting display panel.

The display part DP can include a display area AA (or active area) and a non-display area NA (or non-active area).

The display area AA is an area in which an image is displayed on the display part DP.

In the display area AA, a plurality of sub-pixels constituting a plurality of pixels and a circuit for driving the plurality of sub-pixels can be disposed. The plurality of sub-pixels is minimum units constituting the display area AA, and a display element can be disposed in each of the plurality of sub-pixels, and the plurality of sub-pixels can constitute a pixel. For example, an organic light emitting element including an anode, an organic layer, and a cathode can be disposed in each of the plurality of sub-pixels, but it is not limited thereto. Further, a circuit for driving the plurality of sub-pixels can include a driving element, a wiring, and the like. For example, the circuit can be formed of a thin film transistor, a storage capacitor, a gate line, a data line, or the like, and is not limited thereto.

The non-display area NA is an area where no image is displayed and can surround the display area AA entirely or only in part(s).

FIG. 1 illustrates that the non-display area NA encloses the display area AA having a rectangular shape. However, the shapes and arrangements of the display area AA and the non-display area NA are not limited to the example illustrated in FIG. 1. The display area AA and the non-display area NA can have shapes suitable for a design of an electronic device including the display device 100. For example, another example shape of the display area AA can be a pentagon, a hexagon, a circle, an oval, or the like.

In the non-display area NA, various wirings and circuits for driving the organic light emitting element of the display area AA can be disposed. For example, in the non-display area NA, a link line for transmitting signals to the plurality of sub-pixels and circuits of the display area AA or a driving integrated circuit (IC) such as a gate driver IC or a data driver IC can be disposed, but it is not limited thereto.

Further, the display device 100 can include various additional elements for generating various signals or driving the pixel in the display area AA. In this case, the additional elements for driving the pixels can include an inverter circuit, a multiplexer, an electrostatic discharge (ESD) circuit, and the like. The display device 100 can also include an additional element related to a function other than driving of the pixel. For example, the display device 100 can further include additional elements that provide a touch sensing function, a user authentication function (e.g., fingerprint recognition), a multilevel pressure sensing function, a tactile feedback function, and the like. The above-mentioned additional elements can be located in an external circuit connected to the non-display area NA and/or the connection interface.

The flexible film 180 is a film in which various components are disposed on a base film having flexibility. Specifically, the flexible film 180 is a film for supplying signals to the plurality of sub-pixels and circuits of the display area AA and can be electrically connected to the display part DP. The flexible film 180 can be disposed at one end of the display part DP to supply a power voltage and a data voltage to the plurality of sub-pixels and circuits of the display area AA. The number of flexible films 180 can be variously changed according to design, and is not limited thereto.

Meanwhile, for example, a driving IC such as a gate driver IC and a data driver IC can be disposed on the flexible film 180. The driving IC is a component that processes data for displaying an image and a driving signal for processing the data. The driving IC can be disposed by a chip on glass (COG), a chip on film (COF), a tape carrier package (TCP) method, or the like depending on a mounting method.

Further, the printed circuit board 170 can be disposed on the other end of the flexible film 180 to be connected to the flexible film 180. The printed circuit board 170 is a component that supplies signals to the driving IC. The printed circuit board 170 can supply various signals, such as a driving signal or a data signal, to the driving IC. For example, a data driver for generating data signals can be mounted on the printed circuit board 170, and the generated data signal can be supplied to sub pixels and circuits of the display part DP through the flexible film 180.

Meanwhile, an encapsulation part FSPM can be disposed on the display part DP.

The encapsulation part FSPM can include a sealing member and a reinforcing substrate.

A heat dissipation sheet 160 can be disposed on the encapsulation part FSPM.

According to aspects of the present disclosure, by introducing an encapsulation structure of a multilayer structure including a relatively thick reinforcing substrate, sufficient rigidity and heat dissipation effects can be secured.

Further, the present disclosure is characterized in that a plurality of grooves are formed in the heat dissipation sheet 160, and a thin metal plate is alternately inserted into the plurality of grooves so that the heat dissipation sheet is fastened through the metal plate while maintaining a gap from the encapsulation part FSPM, which will be described in detail with reference to the drawings.

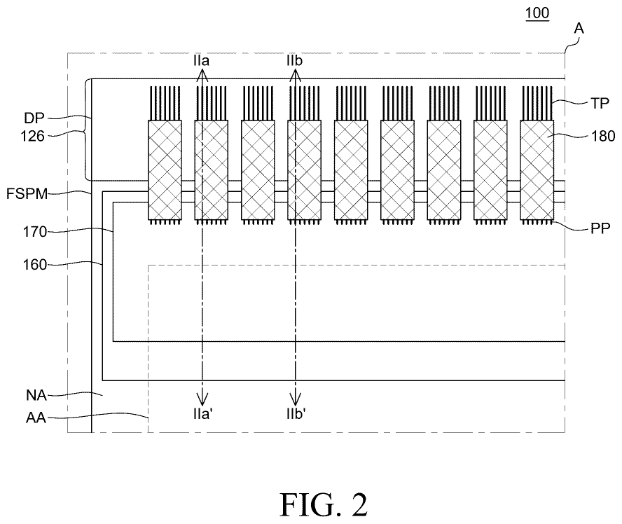

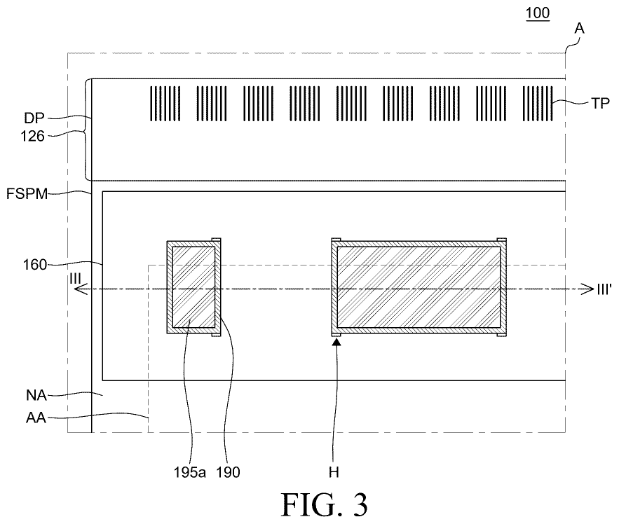

FIGS. 2 and 3 are enlarged views of a part A of FIG. 1.

In particular, FIG. 3 illustrates a part of the display device 100 in which the printed circuit board 170 and the flexible film 180 on the heat dissipation sheet 160 are removed, as compared to FIG. 2.

Referring to FIGS. 2 and 3, an encapsulation part FSPM can be disposed on the display part DP according to an embodiment of the present disclosure.

The encapsulation part FSPM can include a sealing member and a reinforcing substrate.

A heat dissipation sheet 160 can be disposed on the encapsulation part FSPM.

The heat dissipation sheet 160 can be made of a metal material having high thermal conductivity, light weight, and excellent corrosion resistance, such as aluminum (Al), copper (Cu), and silver (Ag).

Meanwhile, a plurality of grooves H can be formed in the heat dissipation sheet 160 of the present disclosure.

The plurality of grooves H can be formed to penetrate the heat dissipation sheet 160.

For example, the plurality of grooves H can be elongated in the arrangement direction of the flexible film 180, for example, in the vertical direction of FIG. 3, and are not limited thereto.

For example, the plurality of grooves H can have an elongated rectangular shape.

The plurality of grooves H can be disposed at regular intervals, and is not limited thereto.

The present disclosure is characterized in that the thin metal plate 190 is alternately inserted into the plurality of grooves H of the heat dissipation sheet 160.

For example, the metal plate 190 can be made of a magnetic metal material having greater rigidity than the heat dissipation sheet 160, such as iron or stainless steel (SUS), and is not limited thereto. However, the metal plate 190 has a relatively thin thickness compared to the heat dissipation sheet 160 so that the metal plate 190 can be inserted into the plurality of grooves H of the heat dissipation sheet 160.

As the metal plate 190 can be alternately inserted into the plurality of grooves H of the heat dissipation sheet 160, the metal plate 190 can be alternately exposed from the upper and lower portions of the heat dissipation sheet 160.

For example, the metal plate 190 can be partially bent when inserted into the groove H of the heat dissipation sheet 160. For example, as the metal plate 190 is fitted into the groove H, a part of the metal plate 190 can be bent, and is not limited thereto.

According to an embodiment of the present disclosure, the metal plate 190 can be inserted into the groove H of the heat dissipation sheet 160 to be spaced apart from the heat dissipation sheet 160.

As described above, the metal plate 190 and the heat dissipation sheet 160 can be inserted into the groove H so that a slight clearance is maintained without being completely in close contact, even when the heat dissipation sheet 160 expands due to heat, excessive pressure is not applied to the metal plate 190, thereby preventing deformation. In addition, the metal plate 190 can be more easily inserted into the groove H and can be easily assembled.

Meanwhile, a first adhesive means 195a can be disposed on the upper surface of the metal plate 190 exposed to the outside.

In addition, a second adhesive means can be disposed on the lower surface of the heat dissipation sheet 160 on which the metal plate 190 is not disposed.

For example, the first adhesive means 195a and the second adhesive means can include an adhesive. In addition, the second adhesive means can further include magnetic particles in addition to the adhesive so as to have both adhesive and magnetic properties. Accordingly, the second adhesive means can serve to magnetically fix the metal plate 190 positioned thereabove. The first and second adhesive means can be referred to or include first and second adhesive members, layers, elements, etc.

The printed circuit board 170 can be disposed on the metal plate 190 and the heat dissipation sheet 160 configured as described above.

The printed circuit board 170 can be a component that supplies signals to the driving IC. The printed circuit board 170 can supply various signals, such as a driving signal or a data signal, to the driving IC.

The printed circuit board 170 can be attached to the metal plate 190 through the first adhesive means 195a. In this case, since the metal plate 190 is spaced apart from the heat dissipation sheet 160 and does not constrain or fix each other, the printed circuit board 170 is also not constrained by the flow and thermal expansion of the heat dissipation sheet 160.

Meanwhile, the flexible film 180 can be disposed at one end of the display part DP and supply a power voltage and a data voltage to the plurality of sub-pixels and circuits of the display area AA. In this case, the flexible film 180 can be a film in which various components are disposed on a base film having flexibility.

For example, one end of the flexible film 180 can be connected to the plurality of pads TP of the pad part 126 to supply a power voltage, a data voltage, etc. to the plurality of sub-pixels and circuits of the display area AA.

For example, a driving IC such as a gate driver IC and a data driver IC can be disposed on the flexible film 180. The driving IC can be a component that processes data for displaying an image and a driving signal for processing the data. The driving IC can be disposed by a chip on glass (COG), a chip on film (COF), a tape carrier package (TCP) method, or the like depending on a mounting method.

Meanwhile, the other end of the flexible film 180 can be connected to the printed circuit board 170. For example, the other end of the flexible film 180 can be connected to the output pad PP of the printed circuit board 170 to be supplied with a power voltage, a data voltage, and the like.

For example, a data driver for generating data signals can be mounted on the printed circuit board 170, and the generated data signal can be supplied to sub pixels and circuits of the display part DP through the flexible film 180.

Meanwhile, as described above, since the printed circuit board 170 is not bound to the flow and thermal expansion of the heat dissipation sheet 160, the flexible film 180 is also not bound to the flow and thermal expansion of the heat dissipation sheet 160.

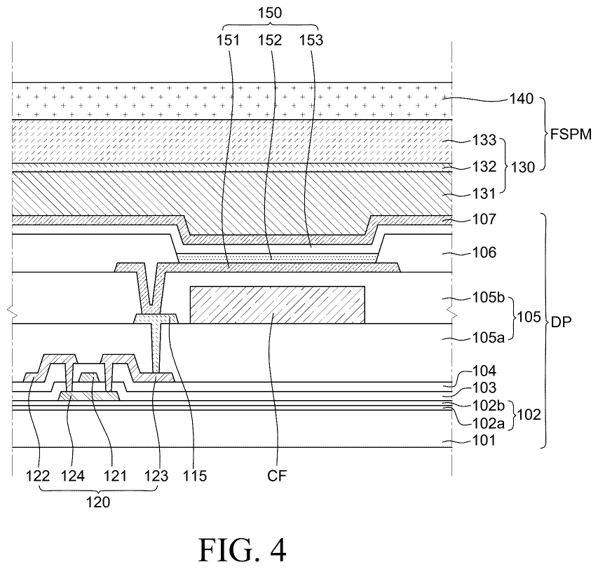

FIG. 4 is a cross-sectional view illustrating a sub pixel of a display device according to an example embodiment of the present disclosure.

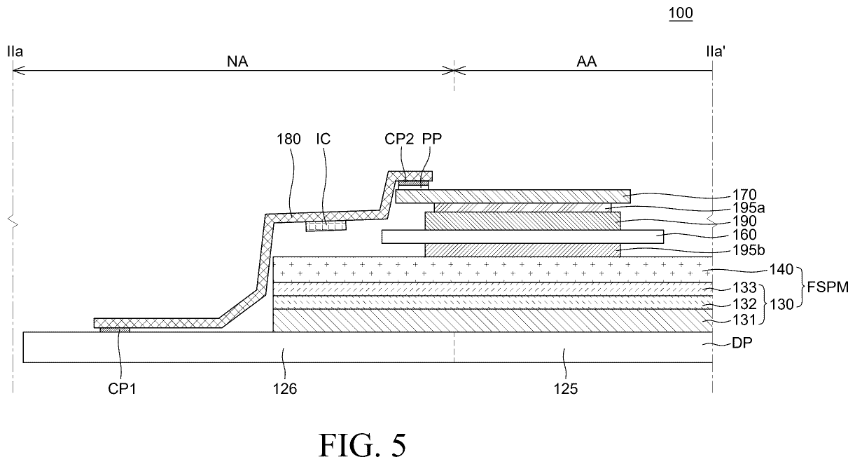

FIG. 5 is a cross-sectional view taken along the line IIa-IIa′ of FIG. 2.

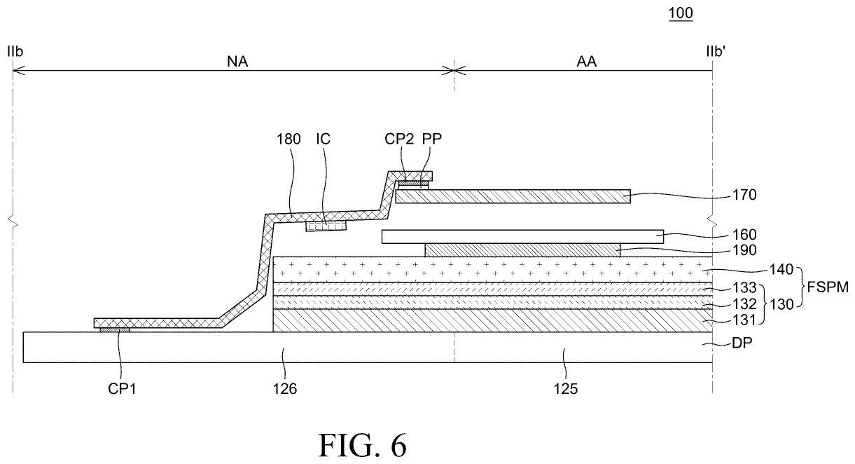

FIG. 6 is a cross-sectional view taken along the line IIb-IIb′ of FIG. 2.

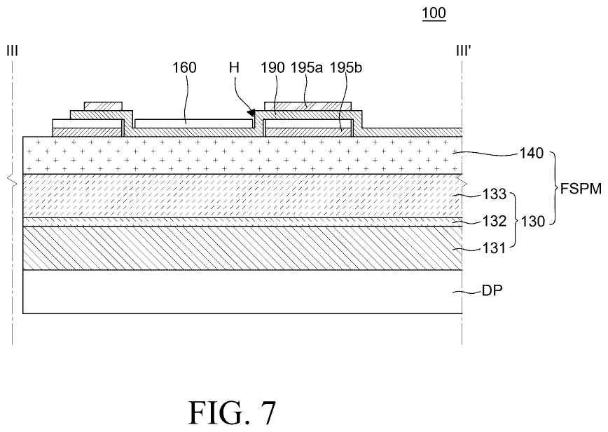

FIG. 7 is a cross-sectional view taken along the line III-III′ of FIG. 3.

Particularly, FIG. 5 illustrates a cross-sectional structure in an area in which the metal plate 190 is located above the heat dissipation sheet 160 as an example. In addition, FIG. 6 illustrates a cross-sectional structure in an area in which the metal plate 190 is located below the heat dissipation sheet 160 as an example.

In FIGS. 5 and 6, for the convenience of description, a pixel part 125 in the display area AA and a pad part 126 in the non-display area NA are schematically illustrated.

Referring to FIGS. 4 to 7, the driving element 120 can be disposed on the substrate 101.

Further, the planarization layer 105 can be disposed on the driving element 120.

Further, an organic light emitting element 150 electrically connected to the driving element 120 can be disposed on the planarization layer 105, and a capping layer 107 can be disposed on the organic light emitting element 150.

The sealing member 130 and the reinforcement substrate 140 can be sequentially disposed on the capping layer 107. The sealing member 130 and the reinforcement substrate 140 can constitute an encapsulation part FSPM, and are not limited thereto, and the reinforcement substrate 140 can be deleted.

However, the display device 100 according to the example embodiment of the present disclosure is not limited to such a laminated structure.

Specifically, the substrate 101 can be a glass or plastic substrate. When the substrate 101 is a plastic substrate, a polyimide-based or polycarbonate-based material can be used to have flexibility. In particular, polyimide can be applied to high-temperature processes and is a material capable of coating, so it is widely used as a plastic substrate.

A buffer layer 102 can be disposed on the substrate 101.

The buffer layer 102 can be a layer for protecting various electrodes and wirings from impurities such as alkali ions flowing out from the substrate 101 or the underlying layers. The buffer layer 102 can have a multilayer structure including a first buffer layer 102a and a second buffer layer 102b, and is not limited thereto. The buffer layer 102 can be made of silicon oxide (SiOx), silicon nitride (SiNx), or a multi-layer thereof.

In addition, the buffer layer 102 can delay diffusion of moisture and/or oxygen permeating the substrate 101. The buffer layer 102 can include a multi-buffer and/or an active buffer. The active buffer protects the active layer 124 which is formed of a semiconductor of the driving element 120 and can perform a function of blocking various types of impurities introduced from the substrate 101. The active buffer can be formed of amorphous silicon (a-Si) or the like.

The driving element 120 can include an active layer 124, a gate electrode 121, a source electrode 122, and a drain electrode 123, and can be electrically connected to the organic light emitting element 150 through the connection electrode 115 to transmit a current or a signal to the organic light emitting element 150.

The active layer 124 can be disposed on the buffer layer 102. The active layer 124 can be made of polysilicon (p-Si), and in this case, a predetermined region can be doped with impurities. Further, the active layer 124 can be made of amorphous silicon (a-Si) or various organic semiconductor materials such as pentacene. Further, the active layer 124 can be made of an oxide semiconductor.

A gate insulating layer 103 can be disposed on the active layer 124.

The gate insulating layer 103 can be formed of an insulating inorganic material such as silicon oxide (SiOx) or silicon nitride (SiNx), or an insulating organic material.

The gate electrode 121 can be disposed on the gate insulating layer 103.

The gate electrode 121 can be made of various conductive materials, for example, nickel (Ni), chromium (Cr), magnesium (Mg), aluminum (Al), molybdenum (Mo), tungsten (W), gold (Au), or an alloy thereof.

An interlayer insulating layer 104 can be disposed on the gate electrode 121.

The interlayer insulating layer 104 can be formed of an insulating material such as silicon oxide (SiOx) or silicon nitride (SiNx), or an insulating organic material.

A contact hole can be formed by selectively removing the gate insulating layer 103 and the interlayer insulating layer 104 to expose the source region and the drain region of the active layer 124. The source electrode 122 and the drain electrode 123 can be formed on the interlayer insulating layer 104 as a single layer or multilayer structure of an electrode material, and can be respectively connected to the source region and the drain region.

If necessary, an additional protective layer made of an inorganic insulating material can be formed to cover the source electrode 122 and the drain electrode 123.

The planarization layer 105 can be disposed on the driving element 120 configured as described above.

The planarization layer 105 can have a multilayer structure including at least two layers. For example, the planarization layer 105 can include a first planarization layer 105a and a second planarization layer 105b. The first planarization layer 105a can be disposed to cover the driving element 120, and can be disposed to expose parts of the source electrode 122 and the drain electrode 123 of the driving element 120.

The planarization layer 105 can extend to the non-display area NA.

The planarization layer 105 can have a thickness of about 2 μm, and is not limited thereto.

The planarization layer 105 can be an overcoat layer, and is not limited thereto.

Meanwhile, a connection electrode 115 for electrically connecting the driving element 120 and the organic light emitting element 150 can be disposed on the first planarization layer 105a. In addition, referring to FIG. 4, various metal layers serving as wiring/electrodes, such as data lines or signal lines, can be disposed on the first planarization layer 105a.

In addition, the color filter CF can be disposed on the first planarization layer 105a, and is not limited thereto, and the color filter CF can be omitted depending on the type of the organic light emitting element 150.

The color filter CF of each sub-pixel can have any one of red, green, and blue colors. In addition, in the case of a sub-pixel in which white is implemented, the color filter CF may not be disposed. The arrangement of red, green and blue can be formed in various ways.

In the case of the bottom emission type, the color filter CF can be located below the anode 151.

Further, the second planarization layer 105b can be disposed on the first planarization layer 105a, the connection electrode 115, and the color filter CF.

For example, in the display part DP of one embodiment of the present disclosure, the planarization layer 105 can be composed of two layers because, as the display part DP becomes higher in resolution, the number of various signal wirings increases. Accordingly, since it is difficult to dispose all wirings on one layer while securing a minimum interval, an additional layer is formed. Due to the addition of the additional layer, for example, the second planarization layer 105b, there is room for wiring arrangement, and it can be easy to design wiring/electrode arrangement. Further, when a dielectric material is used as the planarization layer 105 composed of a multilayer, the planarization layer 105 can also be used for forming a capacitance between the metal layers.

The second planarization layer 105b can be formed to expose a part of the connection electrode 115, and the drain electrode 123 of the driving element 120 and the anode 151 of the organic light emitting element 150 can be electrically connected by the connection electrode 115.

The organic light emitting element 150 can be configured such that the anode 151, a plurality of organic layers 152, and the cathode 153 are sequentially disposed. For example, the organic light emitting element 150 can be composed of an anode 151 formed on the planarization layer 105, an organic layer 152 formed on the anode 151, and a cathode 153 formed on the organic layer 152.

The display device 100 can be implemented in a top emission method or a bottom emission method depending on the emission direction. In the top emission method, a reflective layer made of an opaque conductive material having a high reflectance, for example, silver (Ag), aluminum (Al), gold (Au), molybdenum (Mo), tungsten (W), chromium (Cr), or an alloy thereof can be added under the anode 151 so that light emitted from the organic layer 152 is reflected by the anode 151 and directed upwardly, for example, toward the cathode 153. On the other hand, in the bottom emission type, the anode 151 can be formed of only a transparent conductive material such as indium tin oxide (ITO), indium zinc oxide (IZO), indium gallium zinc oxide (IGZO). Hereinafter, the description will be made on the assumption that the display device 100 of the present disclosure is a bottom emission type.

The bank 106 can be disposed on the planarization layer 105 in the remaining area excluding the emission area. For example, the bank 106 has a bank hole exposing the anode 151 corresponding to the emission area. The bank 106 can be made of an inorganic insulating material such as silicon nitride (SiNx) or silicon oxide (SiOx), or an organic insulating material such as benzocyclobutene (BCB), acrylic resin, or imide resin.

The bank 106 can extend to the non-display area NA.

The bank 106 can have a thickness of about 1 μm, and is not limited thereto.

The organic layer 152 can be disposed on the anode 151 exposed by the bank 106. The organic layer 152 can include a light emitting layer, an electron injection layer, an electron transport layer, a hole transport layer, a hole injection layer, etc.

The organic layer 152 can partially extend to the non-display area NA.

The cathode 153 can be disposed on the organic layer 152.

In the case of the top emission type, the cathode 153 can include a transparent conductive material. For example, the cathode 153 can be formed of indium tin oxide (ITO), indium zinc oxide (IZO), indium gallium zinc oxide (IGZO), or the like. In the case of the bottom emission type, the cathode 153 can include any one of a group formed of a metal material such as gold (Au), silver (Ag), aluminum (Al), molybdenum (Mo), magnesium (Mg), palladium (Pd), copper (Cu) or an alloy thereof. Alternatively, the cathode 153 can be configured by laminating layers made of a transparent conductive material such as indium tin oxide (ITO), indium zinc oxide (IZO), indium gallium zinc oxide (IGZO), and layers made of a metal material such as gold (Au), silver (Ag) aluminum (Al), molybdenum (Mo), magnesium (Mg), palladium (Pd), copper (Cu), or an alloy thereof, and is not limited thereto.

The cathode 153 can partially extend to the non-display area NA.

In the non-display area NA, the cathode 153 can be disposed to cover the side surface of the organic layer 152, and is not limited thereto.

A capping layer 107 made of a material having a high refractive index and a high light absorption rate can be disposed on the organic light emitting element 150 to reduce the diffuse reflection of external light.

The capping layer 107 can be an organic material layer made of an organic material, and can be omitted if necessary.

The capping layer 107 can extend to the non-display area NA.

The encapsulation part FSPM of the multilayer structure composed of the sealing member 130 and the reinforcement substrate 140 can be disposed on the cathode 153, but the present disclosure is not limited thereto, and the reinforcement substrate 140 can be deleted.

A small-sized display panel used in a mobile device and a portable device has a small area of the display panel so that heat generation in an element is rapidly emitted and there is less problem of bonding. However, in a large-sized display panel used in a monitor, tablet, or television receiver, the area of the display panel is large, so that an encapsulation structure for an optimal heat dissipation effect and bonding force is required.

In addition, in order to ensure sufficient rigidity, the display device can further include a separate inner plate on top of the encapsulation substrate. In this case, it is necessary to secure a space for accommodating the separate inner plate, and the weight of the inner plate poses a limitation on thinning and lightening the display device. In addition, a vertical separation space is generated by an air gap generated between the encapsulation substrate and the inner plate corresponding to the thickness of the adhesive tape disposed to adhere the encapsulation substrate and the inner plate, which limits the heat dissipation performance.

Accordingly, an embodiment of the present disclosure is characterized in that a sealing member 130 of the multilayer structure, which can fix the relatively thick reinforcing substrate 140 while removing the separate inner plate and preventing process defects, is applied to the encapsulation part FSPM.

The sealing member 130 according to an embodiment of the present disclosure can include a first adhesive layer 131 facing the substrate 101, a second adhesive layer 133 facing the reinforcement substrate 140, and a metal layer 132 disposed between the first adhesive layer 131 and the second adhesive layer 133.

Each of the first adhesive layer 131 and the second adhesive layer 133 can be made of a polymer material having adhesiveness. For example, the first adhesive layer 131 can be made of any one of olefin-based, epoxy-based, and acrylate-based polymer materials. In addition, the second adhesive layer 133 can be made of any one of olefin-based, epoxy-based, acrylate-based, amine-based, phenol-based, and acid anhydride-based materials that do not contain a carboxyl group. In particular, it is preferable that the second adhesive layer 133 is made of a polymer material in which a carboxyl group is not included to prevent corrosion and to ensure film uniformity of the metal layer 132.

For heat dissipation of the substrate 101, at least the first adhesive layer 131 of the first and second adhesive layers 131 and 133 can be formed of a mixture including an adhesive polymer material and particles of a metal material. For example, the particles of the metal material can be powder made of nickel (Ni). The first adhesive layer 131 in direct contact with the display part DP is composed of a mixture including an adhesive polymer material and particles of a metal material, so that the first adhesive layer 131 can have higher thermal conductivity than the adhesive polymer material.

Likewise, the second adhesive layer 133 can be also formed of a mixture including an adhesive polymer material and particles of a metal material, so that the second adhesive layer 133 can have higher thermal conductivity than the adhesive polymer material.

Accordingly, since the driving heat generated in the display part DP can be more efficiently dissipated through the sealing member 130, the heat dissipation effect on the display part DP can be improved.

Further, in order to prevent moisture permeation to the pixel part 125, the first adhesive layer 131 can be formed of a mixture further including an inorganic filler having hygroscopicity. In this case, the hygroscopic inorganic filler can be at least one of barium oxide (BaO), calcium oxide (CaO), and magnesium oxide (MgO).

Unlike the first adhesive layer 131, the second adhesive layer 133 is not in direct contact with the pixel part 125 so that it is not necessary to include an inorganic filler for preventing moisture permeation of the pixel part 125. Accordingly, the second adhesive layer 133 does not include a hygroscopic inorganic filler, but can include only an adhesive polymer material and particles of a metal material. In this way, the amount of the relatively expensive hygroscopic inorganic filler injected into the sealing member 130 can be reduced, thereby reducing the cost of preparing the sealing member 130.

Further, since the hygroscopic inorganic filler is not included, the mixing ratio of the polymer material included in the second adhesive layer 133 can be increased compared to the first adhesive layer 131, so that the adhesiveness of the second adhesive layer 133 can be improved compared to the adhesiveness of the first adhesive layer 131. Accordingly, as the reinforcement substrate 140 is more firmly fixed to the upper portion of the second adhesive layer 133, the reliability of the bonding force between the display part DP and the reinforcement substrate 140 can be further improved.

Since the first adhesive layer 131 and the second adhesive layer 133 are formed in a multi-layered structure, there is an advantage in that reliability in which a warpage phenomenon in which the display panel is bent can be reduced can also be improved.

The thickness of each of the first adhesive layer 131 and the second adhesive layer 133 can be limited to a threshold thickness or less at which process defects are prevented. Further, the sum of the thicknesses of the first adhesive layer 131 and the second adhesive layer 133 can be limited to a critical thickness or more capable of securing reliability for fixing the reinforcing substrate 140.

For example, the thickness of each of the first and second adhesive layers 131 and 133 can be in the range of 10 um to 100 um.

The metal layer 132 can be made of a metal material. For example, the metal layer 132 can include a metal material such as Al, Cu, Sn, Ag, Fe, Zn and the like.

The metal layer 132 can be introduced to reinforce bonding with the first adhesive layer 131 and the second adhesive layer 133 and implement a stacked structure to reduce warpage.

Specifically, each of the first adhesive layer 131 and the second adhesive layer 133 includes a polymer material having adhesiveness. Accordingly, the metal layer 132 having a relatively hard material is disposed between the first adhesive layer 131 and the second adhesive layer 133 to bond the first adhesive layer 131 and the second adhesive layer 133 to one surface and the other surface of the metal layer 132, respectively, thereby improving the bonding strength.

In this case, the thickness of the metal layer 132 can be limited to a value smaller than the thicknesses of the first adhesive layer 131 and the second adhesive layer 133 to minimize an increase in the thickness of the sealing member 130 caused by the metal layer 132. For example, the thickness of the metal layer 132 can be greater than 10 um and can be within a range smaller than the thickness of each of the first adhesive layer 131 and the second adhesive layer 133.

Since the sealing member 130 according to an embodiment of the present disclosure includes the first adhesive layer 131 and the second adhesive layer 133 separated by the metal layer 132, it can be implemented to have a thickness approximately twice as thick as that of the adhesive material of the single layer without a process defect. Accordingly, since the reinforcing substrate 140 fixed by the sealing member 130 can be provided with a thicker thickness, there is an advantage in that it is possible to easily increase rigidity and improve the heat dissipation effect. For example, when the thickness of the sealing member 130 is within a range of 30 um to 300 um, the thickness of the reinforcement substrate 140 can be implemented to have a thickness in a range of 0.1 mm to 1.5 mm.

For example, the reinforcement substrate 140 can be made of any one of glass and plastic polymers such as PET.

The sealing member 130 and the reinforcement substrate 140 can extend to the non-display area NA to cover a portion of the planarization layer 105 and the bank 106.

As described above, in the present disclosure, by introducing the encapsulation portion FSPM of the multilayer structure including the relatively thick reinforcing substrate 140, the rigidity and heat dissipation effects can be sufficiently secured.

Meanwhile, the heat dissipation sheet 160 can be disposed on the encapsulation part FSPM configured as described above.

The heat dissipation sheet 160 can be made of a metal material having high thermal conductivity, light weight, and excellent corrosion resistance, such as aluminum (Al), copper (Cu), and silver (Ag).

Meanwhile, a plurality of grooves H can be formed in the heat dissipation sheet 160 of the present disclosure.

The plurality of grooves H can be formed to penetrate the heat dissipation sheet 160.

The metal plate 190 can be alternately inserted into the plurality of grooves H of the heat dissipation sheet 160. Accordingly, in some areas, the metal plate 190 can be located above the heat dissipation sheet 160, and in some other areas, the metal plate 190 can be located below the heat dissipation sheet 160.

The metal plate 190 can have a relatively thin thickness compared to the heat dissipation sheet 160 so that the metal plate 190 can be inserted into the plurality of grooves H of the heat dissipation sheet 160. For example, as shown in FIG. 7, while the heat dissipation sheet 160 remains flat, the metal plate 190 can be bent to cross and be inserted into the groove H of the heat dissipation sheet 160.

Further, the metal plate 190 of the present disclosure can be inserted into the groove H of the heat dissipation sheet 160 so as to be spaced apart from the heat dissipation sheet 160.

For example, the metal plate 190 can be made of a magnetic metal material such as iron or stainless steel (SUS), and is not limited thereto.

Meanwhile, a first adhesive means 195a can be disposed on an upper surface of the metal plate 190 located on the heat dissipation sheet 160.

In addition, the second adhesive means 195b can be disposed on the lower surface of the heat dissipation sheet 160 on which the metal plate 190 is not disposed.

For example, the first adhesive means 195a and the second adhesive means 195b can include an adhesive. In addition, the second adhesive means 195b can further include magnetic particles in addition to the adhesive, and is not limited thereto. When the second adhesive means 195b includes magnetic particles, the metal plate 190 on the upper portion thereof can be magnetically fixed.

The printed circuit board 170 can be disposed on the metal plate 190 and the heat dissipation sheet 160 configured as described above.

The printed circuit board 170 can be attached to the metal plate 190 through the first adhesive means 195a.

Further, a plurality of flexible films 180 can be attached to cover edges of the encapsulation part FSPM and the printed circuit board 170 from the pad part 126 of the display part DP.

In this case, a plurality of output pads PP can be disposed on an upper surface of an edge of the printed circuit board 170. Further, a plurality of pads can be disposed on the pad part 126 of the display part DP.

One end of the flexible film 180 can be connected to the pad TP of the pad part 126 through the first connection pad CP1.

In addition, the other end of the flexible film 180 can be connected to the output pad PP of the printed circuit board 170 through the second connection pad CP2.

In this case, a driving IC (IC) such as a gate driver IC and a data driver IC can be disposed on one surface, for example, a lower surface of the flexible film 180.

Hereinafter, a manufacturing process of a display device according to an embodiment of the present disclosure will be described in detail with reference to the drawings.

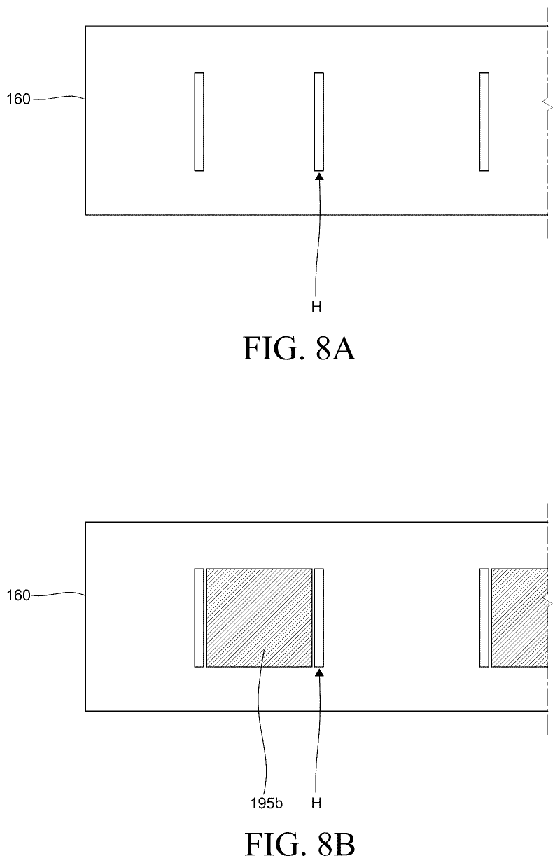

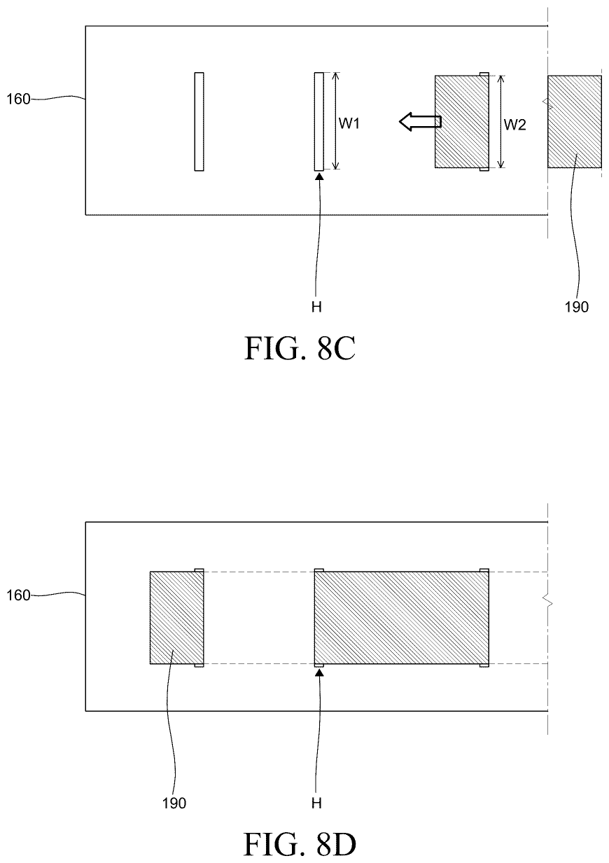

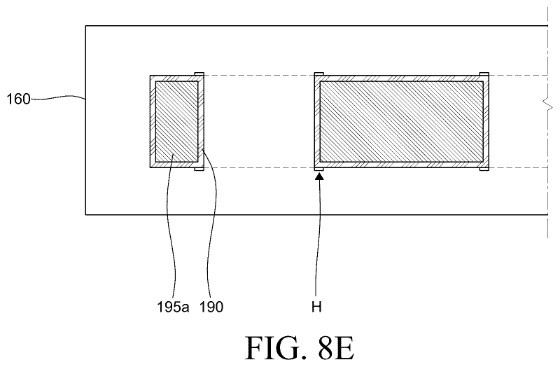

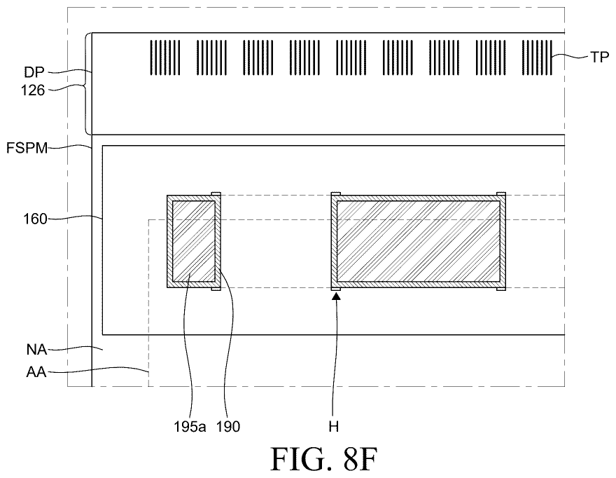

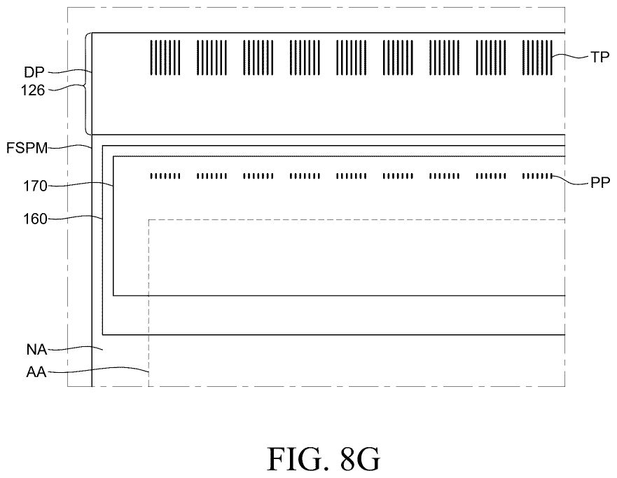

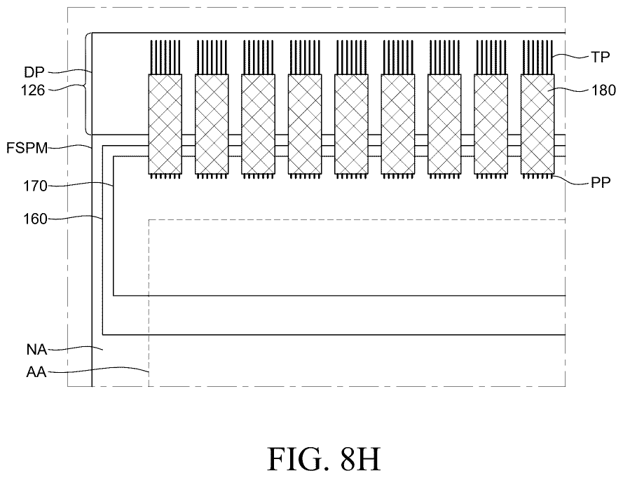

FIGS. 8A to 8H are plan views sequentially illustrating a part of the manufacturing process of the display device of FIG. 1 according to an embodiment of the present disclosure.

Referring to FIG. 8A, a plurality of grooves H can be formed in the heat dissipation sheet 160.

The heat dissipation sheet 160 can be formed of a metal material having high thermal conductivity, light weight, and excellent corrosion resistance, such as aluminum (Al), copper (Cu), and silver (Ag).

The plurality of grooves H can be formed to penetrate the heat dissipation sheet 160.

The plurality of grooves H can be elongated in a direction perpendicular to the longitudinal direction of the heat dissipation sheet 160, and is not limited thereto.

For example, the plurality of grooves H can have an elongated rectangular shape.

The plurality of grooves H can be disposed at regular intervals, and is not limited thereto.

The heat dissipation sheet 160 can be prepared in an appropriate number in consideration of the overall size of the display device.

Thereafter, referring to FIG. 8B, the second adhesive means 195b can be attached to the rear surface of the heat dissipation sheet 160 in which the plurality of grooves H is formed.

For example, the second adhesive means 195b can include an adhesive.

Further, for example, the second adhesive means 195b can further include magnetic particles.

The second adhesive means 195b can be attached to the rear surface of the heat dissipation sheet 160 between the plurality of grooves H. Here, the second adhesive means 195b can be attached to the rear surface of the heat dissipation sheet 160 on which the metal plate 190 is not disposed.

Thereafter, referring to FIGS. 8C and 8D, the thin metal plate 190 can be alternately inserted into the plurality of grooves H of the heat dissipation sheet 160.

Accordingly, the part of the metal plate 190 can be located above the heat dissipation sheet 160, and another part of the metal plate 190 can be located below the heat dissipation sheet 160.

For example, the metal plate 190 can have a width W2 smaller than the width W1 of the groove H to be inserted into the groove H. In addition, the metal plate 190 can have a length shorter than the entire length of the heat dissipation sheet 160, and is not limited thereto. Accordingly, the metal plate 190 according to an embodiment of the present disclosure can be inserted into the groove H of the heat dissipation sheet 160 to be spaced apart from the heat dissipation sheet 160.

For example, the metal plate 190 can be more rigid than the heat dissipation sheet 160, such as iron or stainless steel (SUS), and can be made of a magnetic metal material, and is not limited thereto.

Further, for example, the metal plate 190 can have a thickness smaller than that of the heat dissipation sheet 160 and can be partially bent when inserted into the groove H of the heat dissipation sheet 160.

Thereafter, referring to FIG. 8E, the first adhesive means 195a can be attached to the upper surface of the metal plate 190.

For example, the first adhesive means 195a can include an adhesive.

The first adhesive means 195a can be attached to the upper surface of the metal plate 190 between the plurality of grooves H. Here, the first adhesive means 195a can be positioned above the heat dissipation sheet 160 and attached to the exposed upper surface of the metal plate 190.

Thereafter, referring to FIG. 8F, an encapsulation part FSPM can be formed on the display part DP.

A plurality of pads TP can be formed on the pad part 126 of the display part DP.

Further, the encapsulation part FSPM can be configured as a multilayer structure composed of the sealing member and the reinforcing substrate, and is not limited thereto.

Further, the encapsulation part FSPM can be disposed above the display part DP so that the plurality of pads TP of the display part DP is exposed.

The heat dissipation sheet 160 into which the metal plate 190 is alternately inserted can be attached to the encapsulation part FSPM disposed in this way. For example, the heat dissipation sheet 160 can be attached onto the encapsulation part FSPM through the second adhesive means 195b.

In this case, the metal plate 190 inserted into the groove H of the heat dissipation sheet 160 so as to be spaced apart from the heat dissipation sheet 160 is not constrained by the flow and thermal expansion of the heat dissipation sheet 160.

Next, referring to FIG. 8G, the printed circuit board 170 can be attached onto the encapsulation part FSPM to which the heat dissipation sheet 160 is attached. For example, the printed circuit board 170 can be attached to the metal plate 190 through the first adhesive means 195a. Since the metal plate 190 is spaced apart from the heat dissipation sheet 160 and does not constrain or fix each other, the printed circuit board 170 is also not constrained by the flow and thermal expansion of the heat dissipation sheet 160.

In this case, a plurality of output pads PP can be formed at one end of the printed circuit board 170.

The output pad PP of the printed circuit board 170 can be positioned to correspond to the pad TP of the display part DP.

Next, referring to FIG. 8H, a plurality of flexible films 180 can be attached to cover one end of the printed circuit board 170 from the pad part 126 of the display part DP.

One end of the plurality of flexible films 180 can be connected to the pad TP of the pad part 126 through the first connection pad CP1 of FIG. 5.

In addition, the other end of the flexible film 180 can be connected to the output pad PP of the printed circuit board 170 through the second connection pad CP2 of FIG. 5.

In this case, as described above, since the printed circuit board 170 is not bound to the flow and thermal expansion of the heat dissipation sheet 160, the flexible film 180 is also not bound to the flow and thermal expansion of the heat dissipation sheet 160.

Therefore, a deformation which can be generated when the heat dissipation sheet thermally expands is prevented from being directly transferred to the printed circuit board and the flexible film, thereby suppressing or preventing damage to the flexible film. In addition, it is possible to provide a structural advantage of increasing stability by minimizing the effect from displacement and warpage caused by thermal expansion while maintaining mechanical bonding.

The example embodiments of the present disclosure can also be described as follows:

A display device according to an embodiment of the present disclosure includes a display part configured to display an image, an encapsulation part disposed above the display part, a heat dissipation sheet disposed above the encapsulation part and having a plurality of grooves, and a metal plate alternately inserted into the plurality of grooves, a part of the metal plate can be located above the heat dissipation sheet, and another part of the metal plate can be located below the heat dissipation sheet.

The heat dissipation sheet can be made of aluminum, copper, or silver, and the metal plate can be made of iron or stainless steel.

The plurality of grooves can have an elongated rectangular shape.

The metal plate can be inserted into the groove of the heat dissipation sheet to be spaced apart from the heat dissipation sheet.

The display device can further include a first adhesive means attached to an upper surface of a part of the metal plate and a second adhesive means attached to a lower surface of the heat dissipation sheet on which a part of the metal plate is not disposed.

The first adhesive means and the second adhesive means can include an adhesive.

The second adhesive means can further include magnetic particles.

The display device can further include a printed circuit board disposed on the metal plate and the heat dissipation sheet.

The printed circuit board can be attached to the metal plate through the first adhesive means.

The display device can further include a plurality of flexible films disposed so as to cover one end of the printed circuit board from the pad part of the display part.

The display device can further include a plurality of output pads disposed on an edge upper surface of the printed circuit board and a plurality of pads disposed on a pad part of the display part.

One end of the flexible film can be connected to a pad of the pad part through a first connection pad, and the other end of the flexible film can be connected to an output pad of the printed circuit board through a second connection pad.

The encapsulation part can include a sealing member and a reinforcing substrate, and the sealing member can include a first adhesive layer, a second adhesive layer, and a metal layer disposed between the first adhesive layer and the second adhesive layer.

In a state in which the heat dissipation sheet remains flat, the metal plate can be bent and cross-inserted into the groove of the heat dissipation sheet.

A display device according to another embodiment of the present disclosure includes a display part, an encapsulation part disposed on the display part, a heat dissipation sheet disposed on the encapsulation part and having a plurality of grooves, a metal plate alternately inserted into the plurality of grooves, a printed circuit board disposed on the metal plate and the heat dissipation sheet, and a plurality of flexible films disposed to cover one end of the printed circuit board from a pad part of the display part, the metal plate can be inserted into the plurality of grooves of the heat dissipation sheet so as to be spaced apart from the heat dissipation sheet so as not to be constrained by thermal expansion of the heat dissipation sheet.

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a display part configured to display an image;
an encapsulation part disposed above the display part;
a heat dissipation sheet disposed above the encapsulation part and having a plurality of grooves; and
a metal plate alternately inserted into the plurality of grooves of the heat dissipation sheet,
wherein a part of the metal plate is located above the heat dissipation sheet and another part of the metal plate is located below the heat dissipation sheet.

2. The display device according to claim 1, wherein the heat dissipation sheet includes aluminum (Al), copper (Cu) or silver (Ag), and
the metal plate includes iron (Fe) or stainless steel (SUS).

3. The display device according to claim 1, wherein each of the plurality of grooves has an elongated rectangular shape.

4. The display device according to claim 1, wherein the metal plate is inserted into one of the plurality of grooves of the heat dissipation sheet so as to be spaced apart from the heat dissipation sheet.

5. The display device according to claim 1, further comprising:
a first adhesive means attached to an upper surface of a part of the metal plate; and
a second adhesive means attached to a lower surface of the heat dissipation sheet on which a part of the metal plate is not disposed.

6. The display device according to claim 5, wherein each of the first adhesive means and the second adhesive means includes an adhesive.

7. The display device according to claim 6, wherein the second adhesive means further includes magnetic particles.

8. The display device according to claim 5, further comprising:
a printed circuit board disposed above the metal plate and the heat dissipation sheet.

9. The display device according to claim 8, wherein the printed circuit board is attached to the metal plate through the first adhesive means.

10. The display device according to claim 8, further comprising:
a plurality of flexible films disposed so as to cover one end of the printed circuit board from a pad part of the display part.

11. The display device according to claim 10, further comprising:
a plurality of output pads disposed above an edge upper surface of the printed circuit board; and
a plurality of pads disposed above the pad part of the display part.

12. The display device according to claim 11, wherein one end of a flexible film among the plurality of flexible films is connected to a pad of the pad part through a first connection pad and
another end of the flexible film among the plurality of flexible films is connected to an output pad of the printed circuit board through a second connection pad.

13. The display device according to claim 1, wherein the encapsulation part includes a sealing member and a reinforcing substrate.

14. The display device according to claim 13, wherein the sealing member includes a first adhesive layer, a second adhesive layer, and a metal layer disposed between the first adhesive layer and the second adhesive layer.

15. The display device according to claim 1, wherein when the heat dissipation sheet remains flat, the metal plate is bent to be cross-inserted into one of the plurality of grooves of the heat dissipation sheet.

16. A display device comprising:
a display part;
an encapsulation part disposed above the display part;
a heat dissipation sheet disposed above the encapsulation part and having a plurality of grooves;
a metal plate;
a printed circuit board disposed above the metal plate and the heat dissipation sheet; and
a plurality of flexible films disposed so as to cover one end of the printed circuit board from a pad part of the display part,
wherein the metal plate is inserted into the plurality of grooves of the heat dissipation sheet so as to be spaced apart from the heat dissipation sheet, and is not constrained by a thermal expansion of the heat dissipation sheet.

17. The display device according to claim 16, wherein the encapsulation part includes a sealing member and a reinforcing substrate disposed above the sealing member.

18. The display device according to claim 16, further comprising:
a first adhesive member coupled to a first surface of a part of the metal plate; and
a second adhesive member coupled to a second surface of the heat dissipation sheet on which a part of the metal plate is disposed.

19. The display device according to claim 18, wherein the second adhesive member includes an adhesive and magnetic particles.

20. The display device according to claim 16, further comprising:
a printed circuit board disposed above the metal plate and the heat dissipation sheet.
